(19) United States
(12) Patent Application Publication
(10) Pub. No.: US 2009/0203221 A1
(43) Pub. Date: Aug. 13, 2009

(54) APPARATUS AND METHOD FOR INCORPORATING COMPOSITION INTO SUBSTRATE USING NEUTRAL BEAMS

(75) Inventors: Geun-young YEOM, Seoul (KR); Byoung-jae Park, Gyeryong-si (KR); Sung-woo Kim, Seoul (KR)

Correspondence Address: Ballard Spahr Andrews & Ingersoll, LLP, SUITE 1000, 999 PEACHTREE STREET, ATLANTA, GA, 30309-3915, US

(73) Assignee: SUNGKYUNKWAN UNIVERSITY Foundation, Suwon-si (KR)

(21) Appl. No.: 12/031,540

(22) Filed: Feb. 14, 2008

(30) Foreign Application Priority Data
Feb. 11, 2008 (KR) 2008-0012135

(51) Int. Cl. H01L 21/3115; B05B 5/00

(52) U.S. Cl. 438/761; 118/640; 257/E21.247

(57) ABSTRACT

An apparatus and method for incorporating a composition into a substrate using neutral beams are provided to repeatedly process an oxide layer using the neutral beams having low energy to minimize electrical damage to the oxide layer and improve characteristics of the oxide layer. The apparatus is mounted in a plasma generating chamber, and includes: an ion beam generating gas inlet, which injects a gas for generating ion beams; an ion source, which generates the ion beams having a polarity from the gas introduced through the ion beam generating gas inlet; a grid assembly, which is installed on one end of the ion source; a reflector, which is aligned with the grid assembly and converts the ion beams to the neutral beams; and a stage, on which the substrate is placed on a traveling path of the neutral beams. Formation of the oxide layer and application of the neutral beams are repeatedly performed on the substrate so as to improve the characteristics of the oxide layer.

### CROSS-REFERENCE TO RELATED APPLICATION

This application claims the benefit of Korean Patent Application No. 2008-0012135, filed Feb. 11, 2008, the disclosure of which is hereby incorporated herein by reference in its entirety.

### BACKGROUND OF THE INVENTION

1. Field of the Invention

The present invention relates to an apparatus and method for incorporating a composition into a substrate using neutral beams in order to improve characteristics of the substrate, and more particularly, to an apparatus and method for incorporating a composition into a substrate using neutral beams, in which formation of an oxide layer and application of the neutral beams are repeatedly performed twice or more on the substrate to be processed, thereby increasing uniformity of the applied neutral beams.

2. Description of the Related Art

With high integration of semiconductor devices, the area of a memory cell is being reduced. This acts as a serious obstacle to increasing the integration of a non-volatile memory device having a plurality of cell transistors.

Thus, a silicon-oxide-nitride-oxide-silicon (SONOS) non-volatile memory device, which has a single gate electrode as in a metal oxide semiconductor field effect transistor (MOSFET) and can trap electric charges, has been proposed. The SONOS non-volatile memory device has advantages in that it can be easily fabricated and it can be easily integrated with a peripheral region or a logic region of an integrated circuit.

FIG. 1 is a cross-sectional view illustrating the structure of a conventional SONOS device.

As illustrated in FIG. 1, the SONOS device includes a lower insulating layer 130, a charge storage layer 140, an upper insulating layer 150, and a gate electrode, which are sequentially staked on a substrate 110 having an isolation layer 120. At this time, the lower and upper insulating layers 130 and 150 are formed of a silicon oxide (SiO₂) layer using chemical vapor deposition, and the charge storage layer 140 is formed of a silicon nitride (Si₃N₄) layer.

The SONOS device having this structure is a floating trap memory device rather than a floating gate memory device that is a flash memory device, and performs a program operation in a manner such that electric charges are stored in the charge storage layer 140, formed of a nitride layer, between the lower and upper insulating layers 130 and 150.

However, since the nitride layer used as the charge storage layer 140 has a too small trap site, many electric charges are not stored in the nitride layer. Therefore, the program operation for storing the electric charges in the trap site and the erase operation for eliminating the electric charges are reduced in speed.

Thus, in order to maximize performance of the non-volatile memory device, charge trap flash (CTF) technology, which makes use of a metal layer or a charge blocking layer which has a high work function as the gate electrode and of a high-k dielectric layer, is employed.

For example, a tantalium-aluminium oxide-nitride-oxide-silicon (TANOS) or silicon-aluminium oxide-nitride-oxide-silicon (SANOS) non-volatile memory device, which makes use of a TaN layer as the gate electrode and an aluminum oxide layer as a high-k dielectric layer, has been proposed.

### SUMMARY OF THE INVENTION

The present invention provides an apparatus and method for incorporating a composition into a substrate using neutral beams, in which the neutral beams are applied to an oxide layer twice or more so as to be uniformly applied to the substrate to be processed.

The present invention also provides an apparatus and method for incorporating a composition into a substrate using neutral beams, in which the neutral beams are uniformly applied to an oxide layer, thereby performing efficient composition incorporation on a next-generation semiconductor device.

The present invention also provides an apparatus and method for incorporating a composition into a substrate using neutral beams, in which the neutral beams having low energy are applied to an oxide layer formed on the substrate to be processed, thereby preventing the oxide layer from being etched, minimizing damage to the oxide layer, and preventing surface diffusion caused by post treatment such as heat treatment.

In other words, the present invention is different from known ion implantation in that the neutral beams are used within an energy range in which the oxide layer is hardly etched. An apparatus for this ion implantation accelerates ionized dopants at a high speed, and thereby implants the accelerated dopants into a surface of the substrate. In a semiconductor fabrication process, the ion implantation is to endow atomic ions having electrical characteristics with great energy enough to penetrate the surface of the substrate, and implant the atomic ions into the substrate, i.e., the non-conductor.

According to one aspect of the present invention, there is provided an apparatus for incorporating a composition into a substrate using neutral beams, which is mounted in a plasma generating chamber. The apparatus includes: an ion beam generating gas inlet, which injects a gas for generating ion beams; an ion source, which generates the ion beams having a polarity from the gas introduced through the ion beam generating gas inlet; a grid assembly, which is installed on one end of the ion source; a reflector, which is aligned with the grid assembly and converts the ion beams to the neutral beams; and a stage, on which the substrate is placed on a traveling path of the neutral beams. Formation of the oxide layer and application of the neutral beams are repeatedly performed on the substrate so as to improve characteristics of the oxide layer.

Here, the characteristics of the oxide layer may be improved by processing the oxide layer using the neutral beams having a low energy of 5 eV to 100 eV such that there is almost no change in thickness of the oxide layer.

Further, the characteristics of the oxide layer may be improved by processing the oxide layer using the neutral beams having a low energy of 10 eV.

Also, the gas introduced through the ion beam generating gas inlet may include one selected from the group consisting of nitrogen series, oxygen series, CₓF_{y} series, and fluorine series.

Meanwhile, the substrate may be formed of SiO₂, and electrical characteristics of a gate oxide layer may be improved by incorporation using the neutral beams.

Further, the substrate may be formed of a high-k material such as Al₂O₃, HfO₂, TiO₂, ZrO₂, Y₂O₃, Ta₂O₅, or La₂O₃, and electrical characteristics of the oxide layer may be improved by incorporation using the neutral beams.

In addition, the substrate may include one of a silicon-oxide-nitride-oxide-silicon (SONOS) substrate, a tantalium-aluminium oxide-nitride-oxide-silicon (TANOS) substrate and a silicon-aluminium oxide-nitride-oxide-silicon (SANOS) substrate.

According to another aspect of the present invention, there is provided a method of incorporating a composition into a substrate using neutral beams. The method includes: injecting a gas for generating ion beams; generating the ion beams having a polarity from the injected gas; converting the ion beams to neutral beams; and repeatedly performing formation of an oxide layer and application of the neutral beams on the substrate to improve characteristics of the oxide layer, wherein the characteristics of the oxide layer are improved by processing the oxide layer using the neutral beams having a low energy of 5 eV to 100 eV such that there is almost no change in thickness of the oxide layer.

### BRIEF DESCRIPTION OF THE DRAWINGS

The above and other advantages of the present invention will become readily apparent by reference to the following detailed description when considered in conjunction with the accompanying drawings wherein:

FIG. 1 is a cross-sectional view illustrating the structure of a conventional silicon-oxide-nitride-oxide-silicon (SONOS) device;

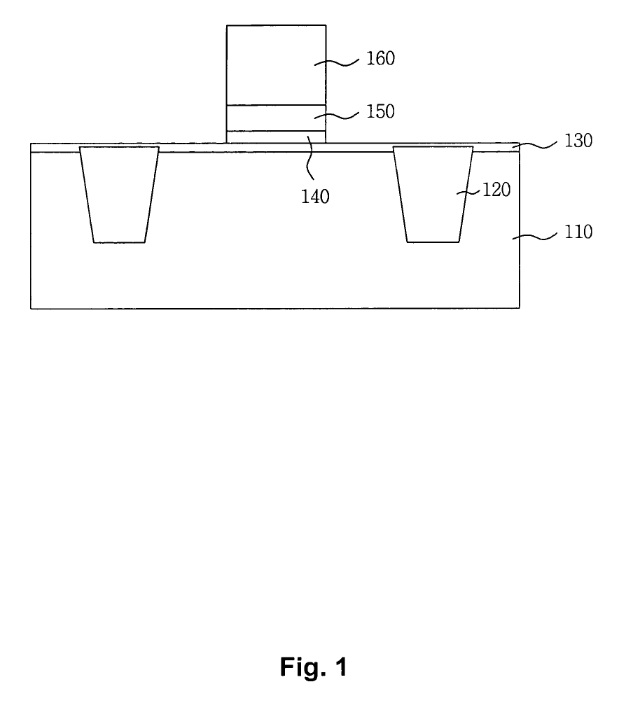

FIG. 2 is a cutaway exploded perspective view of an apparatus for incorporating a composition into a substrate using neutral beams according to the present invention;

FIG. 3 illustrates the state in which the apparatus for incorporating a composition into a substrate using neutral beams illustrated in FIG. 2 is mounted in a plasma generating chamber;

FIG. 4 is a graph showing the results obtained by measuring a change in the depth profile of an oxide layer using secondary ion mass spectrometry (SMIS) after a target substrate is subjected to surface treatment by the composition incorporating apparatus illustrated in FIG. 3;

FIG. 5 is a graph showing characteristics of a memory fabricated using the apparatus for incorporating a composition into a substrate using neutral beams according to the present invention;

FIG. 6 illustrates a conventional process of processing a substrate using neutral beams; and

FIG. 7 is a schematic cross-sectional view illustrating a process of forming an oxide layer on a target substrate and a process of applying neutral beams to the oxide layer using the apparatus for incorporating a composition into a substrate using neutral beams according to the present invention.

### DESCRIPTION OF THE EMBODIMENTS

Hereinafter, the present invention will be explained in detail with reference to the accompanying drawings.

First, the configuration of an apparatus for implementing a method of incorporating a composition into a substrate using neutral beams according to the present invention will be described with reference to the accompanying drawings.

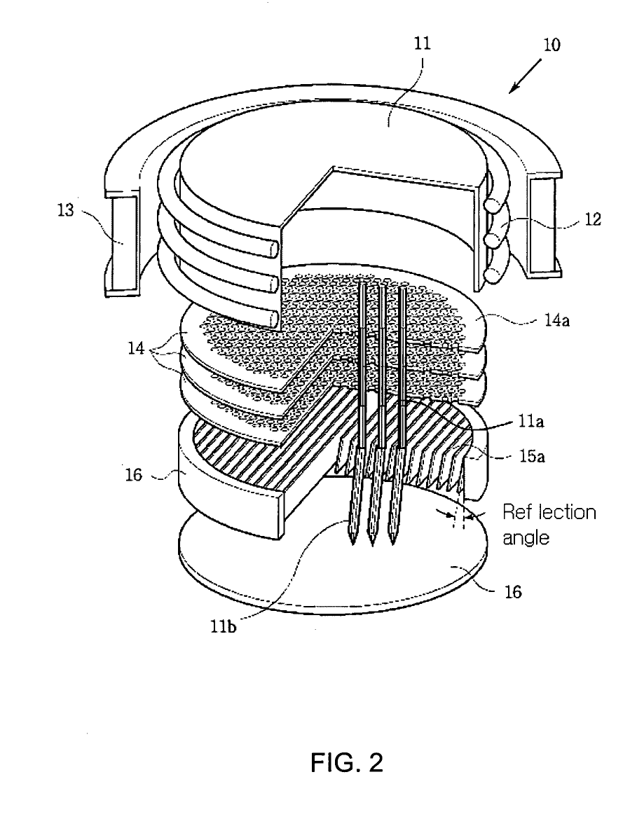

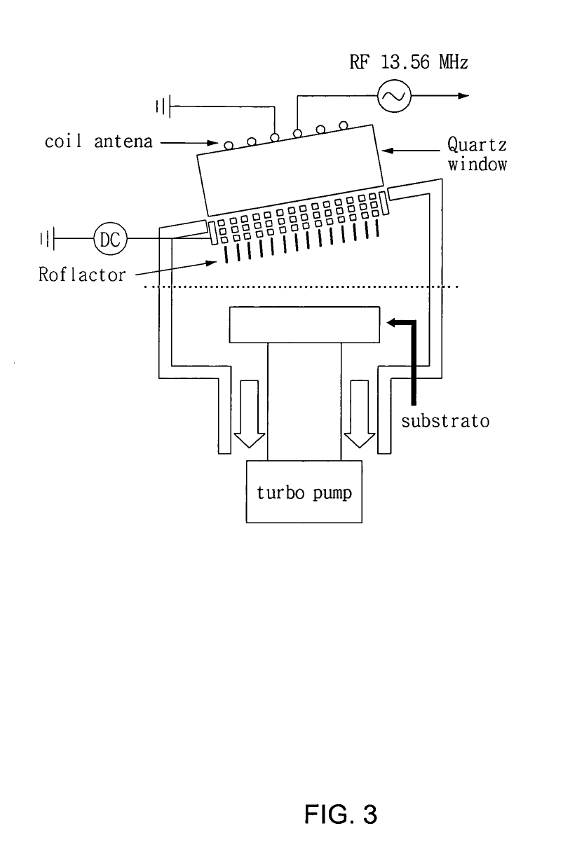

FIG. 2 is a cutaway exploded perspective view of an apparatus for incorporating a composition into a substrate using neutral beams according to the present invention. FIG. 3 illustrates the state in which the apparatus for incorporating a composition into a substrate using neutral beams illustrated in FIG. 2 is mounted in a plasma generating chamber.

The apparatus 10 for incorporating a composition into a substrate using neutral beams according to the present invention includes an ion source 11, an induction coil 12, an electromagnet 13, a grid assembly 14, and a reflector 15.

Here, the ion source 11 may extract and accelerate ion beams 11a having a predetermined polarity, and the induction coil 12 is wound around the ion source 11.

The electromagnet 13 applies an electromagnetic field to the induction coil 12. The grid assembly 14 is located under the ion source 11, and has three grids, each of which is provided with a plurality of grid holes 14a through which the ion beams 11a passes.

The reflector 15 is in close contact with the grid assembly 14, and has a plurality of reflecting plates 15a corresponding to the grid holes 14a of the grid assembly 14. The reflector 15 reflects the ion beams 11a, which pass through the grid holes 14a, onto the reflecting plates 15a, and converts the reflected ion beams to neutral beams 11b.

Further, the composition incorporating apparatus 10 includes a stage, on which a substrate 16 to be processed (hereinafter, referred to as a “target substrate”), a wafer, may be positioned on a traveling path of the neutral beams 11b.

Preferably, a retarding grid is additionally installed between the reflector 15 and the stage so as to control directionality and accelerating energy of the neutral beams 11b. A diameter of the reflecting plate 15a may be constructed to be equal to or greater than a diameter of each grid hole 14a.

Further, the grid assembly 14 has a cylindrical shape, and is provided with protrusions along an outer circumferential edge of the bottom surface thereof. The reflector 15 has a cylindrical shape, and is provided with protrusions, which may be inserted into the respective protrusions of the grid assembly 14, along an outer circumferential edge of the top surface thereof.

Furthermore, the reflecting plates 15a are inclined to the direction, in which the ion beams 11a travel straight through the grid holes 14a, at a predetermined angle, such that the ion beams 11a are reflected from the reflecting plates 15a.

Here, the reflecting plates 15a of the reflector 15 may be arranged to be inclined to the central axis of the reflector 15 at a predetermined angle or to be parallel to the central axis of the reflector 15. The protrusions of the reflector 15, which are formed along the outer circumferential edge of the top surface of the reflector 15, may be constructed to be inclined at a predetermined angle.

According to the present invention, the ion source 11 includes various types of ion sources. The reflector 15 is formed of a semiconductor substrate, a silicon dioxide or metal substrate, or a graphite substrate. Each ion beam 11a, which is incident through the grid holes 14a of the grid assembly 14, may be constructed at an incident angle from 5 to 15 degrees.

In the present invention, the ion source 11 may generate the ion beams 11a, and the reflector 15 is installed between the ion source 11 and the stage on which the target substrate 16, the wafer, is placed, so as to reflect the ion beams 11a having a predetermined incident angle. Thereby, the neutral beams 11b may be obtained.

In order words, according to the present invention, the neutral beams are used as an ion implantation source for processing a surface of the substrate, so that electrical characteristics can be improved in a next generation device such as a tantalium-aluminium oxide-nitride-oxide-silicon (TANOS) device, a silicon-aluminium oxide-nitride-oxide-silicon (SANOS) device, etc. without causing electrical and physical damages to the target substrate 16 due to the ion beam as in the prior art.

To this end, the composition incorporating apparatus 10 of FIG. 3 includes a plasma generating chamber, three grids that sequentially overlap each other, and a reflector. Here, the ion beams are accelerated by applying a positive voltage to the first grid, the uppermost grid, of the three grids, which is adjacent to the plasma generating chamber, and an optical axis of each beam is adjusted by applying a negative voltage to the second grid, the intermediate grid. Further, the third grid, the lowermost grid, and the reflector are grounded to convert the extracted ion beams to the neutral beams, so that the electrical damage to the target substrate is minimized.

Further, in the present invention, an available gas includes nitrogen series, oxygen series, CₓF_{y} series, fluorine series, and so on. The target substrate 16 is formed of high dielectric constant materials, i.e. high-k materials, such as Al₂O₃, HfO₂, TiO₂, ZrO₂, Y₂O₃, Ta₂O₅, and La₂O₃ including SiO₂.

According to the present invention, the grid assembly 14 and the reflector 15, which are located under the ion source 11, are in close contact with each other, so that the ion beams 11a can be prevented from being leaked in an undesired direction, thus remarkably reducing contamination. Thereby, neutron flux of the neutral beams 11b may be considerably increased. Further, since a space occupied by the reflector 15 may be reduced. As a result, the composition incorporating apparatus 10 may be made small and inexpensive.

The ion beams may be accelerated by voltage application. The grid assembly having the plurality of grid holes through which the ion beams can pass is disclosed in Korean Patent No. 0380660, granted to the present applicant, and so the description thereof will be omitted.

Now, a method of processing the target substrate, the wafer, using the composition incorporating apparatus illustrated in FIG. 3 will be described.

A gas for generating the ion beams is injected through an ion beam generating gas inlet, which is not shown. Then, the ion gas, which is injected through the ion beam generating gas inlet, is generated to the ion beams having a polarity by the ion source 11. The generated ion beams 11 pass through the grid assembly 14 and the reflector 15, and then are converted to the neutral beams. The neutral beams are applied to the target substrate 16, and process the target wafer 16.

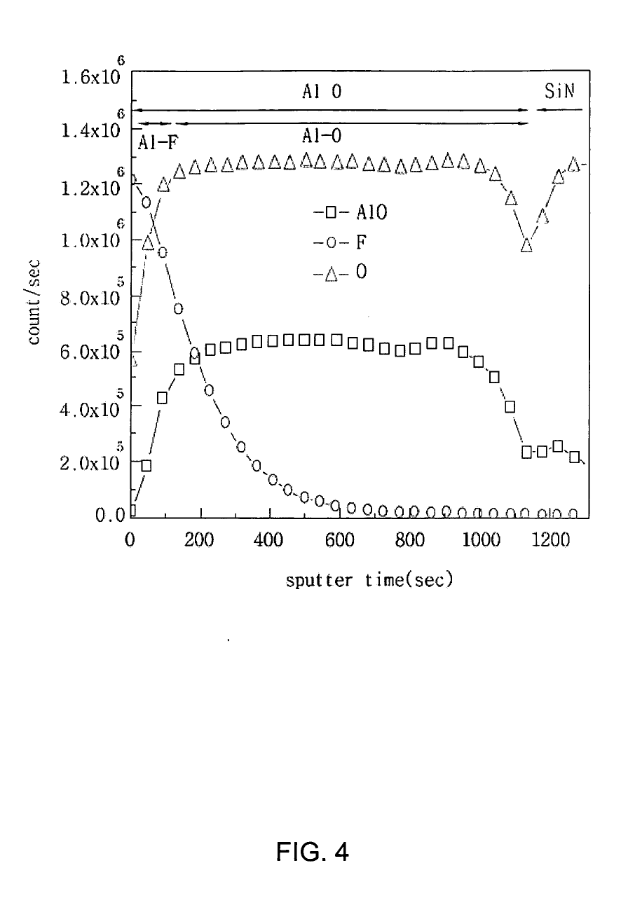

FIG. 4 is a graph showing the results obtained by measuring a change in the depth profile of an oxide layer using secondary ion mass spectrometry (SMIS) after a target substrate is subjected to surface treatment by the composition incorporating apparatus illustrated in FIG. 3. Here, Al₂O₃ was processed by the neutral beams having low energy, and then a depth profile was measured using the SIMS. As a result, it could be found that the neutral beam processing of Al₂O₃ formed Al—F bonds to thereby improve characteristics of the oxide layer.

Further, in the apparatus for incorporating a composition into a substrate using neutral beams according to the present invention, in order to improve the characteristics of the oxide layer, i.e., the target layer deposited on the target substrate, neutral beams having a low energy of 5 eV to 100 eV are used such that there is almost no change in thickness of the oxide layer.

Preferably, the oxide layer of the target substrate is processed by neutral beams having an energy of 10 eV so as to minimize electrical damage to the oxide layer.

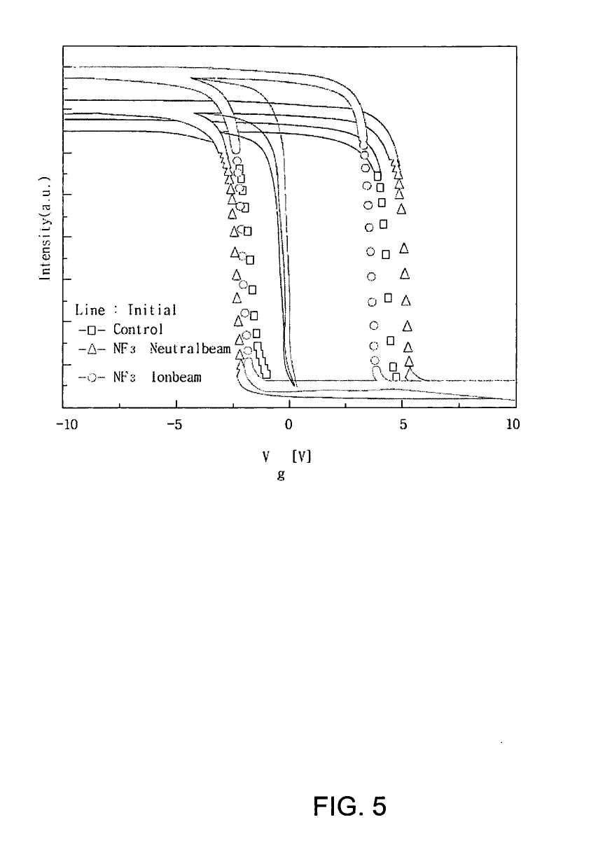

FIG. 5 is a graph showing characteristics of a memory device fabricated using an apparatus for incorporating a composition into a substrate using neutral beams according to the present invention. As shown in FIG. 5, neutral beams are applied to the oxide layer deposited on the target substrate using the apparatus for incorporating a composition into a substrate using neutral beams according to the present invention.

At this time, the neutral beams are applied to the oxide layer with a low energy of 10 eV or less such that the oxide layer deposited on the target substrate does not undergo electrical damage, i.e. such that the oxide layer deposited on the target substrate is not etched, thereby incorporating the composition into the target substrate.

In this case, it will be seen from FIG. 5 that characteristics of the memory device including the oxide layer is improved.

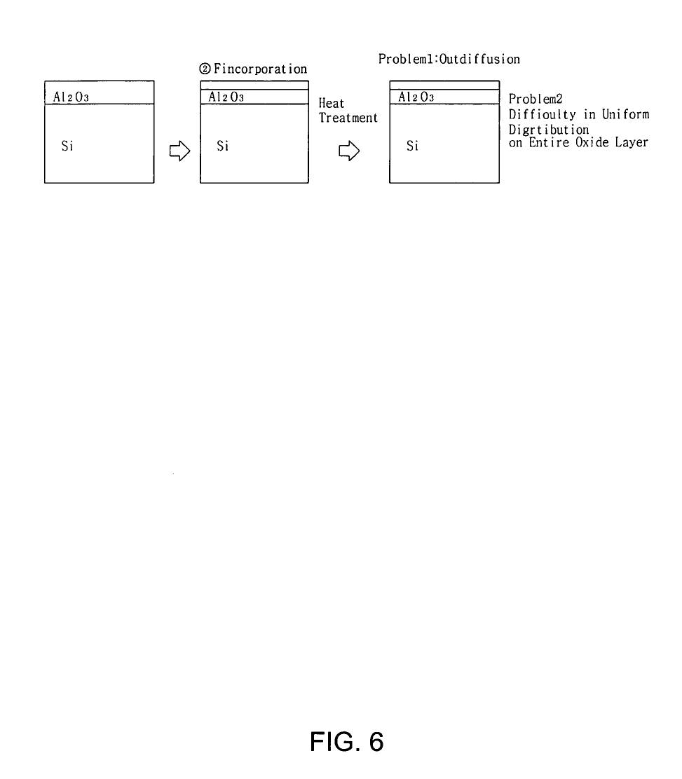

FIG. 6 illustrates a conventional process of processing a substrate using neutral beams. As illustrated in FIG. 6, in the conventional process of processing a target substrate using neutral beams, the neutral beam is applied only to the top surface of the oxide layer, and thus neutral ionic species implanted to the target substrate are diffused to the outside of the oxide layer through post treatment such as heat treatment.

Thus, the neutral ionic species are lost by the diffused amount. Simultaneously, the neutral beams are not uniformly applied to the overall target substrate, so that a uniform oxide layer cannot be formed.

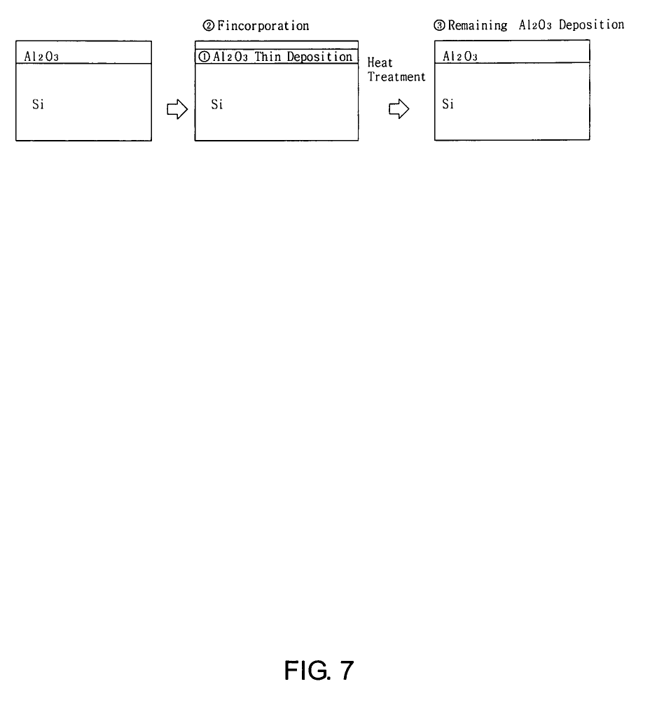

FIG. 7 is a schematic cross-sectional view illustrating a process of forming an oxide layer on a target substrate, and a process of applying neutral beams to the oxide layer using an apparatus for incorporating a composition into a substrate using neutral beams according to the present invention. As illustrated in FIG. 7, both the process of forming the oxide layer on the target substrate and the process of applying neutral beams to the oxide layer are performed at least twice.

More specifically, as illustrated in FIG. 7, the process of depositing a predetermined amount of Al₂O₃ to form a thin oxide layer and the process of applying neutral beams to the oxide layer are repeated. Then, when heat treatment is performed, the remaining amount of Al₂O₃ is deposited. These processes are performed at least twice when the thickness of the oxide layer reaches the half of a desired thickness or at a desired position of the oxide layer.

Thus, when the oxide layer is processed twice or more as in the present invention, the neutral ionic species can be uniformly distributed throughout the oxide layer after post treatment such as heat treatment.

As described above, an apparatus and method for incorporating a composition into a substrate using neutral beams according to the present invention can improve equipment and process technology that may be generally used for a next-generation semiconductor device such as a tantalium-aluminium oxide-nitride-oxide-silicon (TANOS) device, a silicon-oxide-nitride-oxide-silicon (SONOS) device, and so on.

Further, in the apparatus and method for incorporating a composition into a substrate using neutral beams according to the present invention, the surface treatment is repeatedly performed on the oxide layer of the semiconductor device using ions, which are generated from the composition incorporating apparatus, i.e. the neutral beam generator so as to have a low energy of 10 eV or less, so that electrical damage to the oxide layer can be minimized. In order words, the ions of O, N, F, or so on are incorporated into the oxide layer, so that electrical characteristics of the oxide layer can be improved.

In this manner, the present invention is directed to improve the electrical characteristics of the oxide layer using the neutral beams. At this time, the use of the neutral beams can prevent electrical damage to the oxide layer, which may occur in an existing method using plasma, so that the characteristics of the oxide layer can be improved. Particularly, when the neutral beams are applied to a gate oxide layer of the semiconductor device, the electrical characteristics of the oxide layer may be prevented from being degraded by plasma damage, which may occur in the existing method.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. An apparatus for incorporating a composition into a substrate using neutral beams, which is mounted in a plasma generating chamber, the apparatus comprising:
an ion beam generating gas inlet, which injects a gas for generating ion beams;
an ion source, which generates the ion beams having a polarity from the gas introduced through the ion beam generating gas inlet;
a grid assembly, which is installed on one end of the ion source;
a reflector, which is aligned with the grid assembly and converts the ion beams to the neutral beams; and
a stage, on which the substrate is placed on a traveling path of the neutral beams,
wherein formation of the oxide layer and application of the neutral beams are repeatedly performed on the substrate so as to improve characteristics of the oxide layer.

2. The apparatus of claim 1, wherein the characteristics of the oxide layer are improved by processing the oxide layer using the neutral beams having a low energy of 5 eV to 100 eV such that there is almost no change in thickness of the oxide layer.

3. The apparatus of claim 2, wherein the characteristics of the oxide layer are improved by processing the oxide layer using the neutral beams having an energy of 10 eV.

4. The apparatus of claim 3, wherein the gas introduced through the ion beam generating gas inlet includes one selected from the group consisting of nitrogen series, oxygen series, CₓF_{y} series, and fluorine series.

5. The apparatus of claim 4, wherein the substrate is formed of SiO₂, and electrical characteristics of a gate oxide layer are improved by incorporation using the neutral beams.

6. The apparatus of claim 4, wherein the substrate is formed of a high-k material such as Al₂O₃, HfO₂, TiO₂, ZrO₂, Y₂O₃, Ta₂O₅, or La₂O₃, and electrical characteristics of the oxide layer are improved by incorporation using the neutral beams.

7. The apparatus of claim 5, wherein the substrate includes one of a silicon-oxide-nitride-oxide-silicon (SONOS) substrate, a tantalium-aluminium oxide-nitride-oxide-silicon (TANOS) substrate and a silicon-aluminium oxide-nitride-oxide-silicon (SANOS) substrate.

8. A method of incorporating a composition into a substrate using neutral beams, comprising:
injecting a gas for generating ion beams;
generating the ion beams having a polarity from the injected gas;
converting the ion beams to neutral beams; and
repeatedly performing formation of an oxide layer and application of the neutral beams on the substrate to improve characteristics of the oxide layer,
wherein the characteristics of the oxide layer are improved by processing the oxide layer using the neutral beams having a low energy of 5 eV to 100 eV such that there is almost no change in thickness of the oxide layer.

9. The method of claim 8, wherein the gas introduced through the ion beam generating gas inlet includes one selected from the group consisting of nitrogen series, oxygen series, CₓF_{y} series, and fluorine series.

10. The method of claim 9, wherein the substrate is formed of SiO₂, and electrical characteristics of a gate oxide layer are improved by incorporation using the neutral beams.

11. The method of claim 9, wherein the substrate is formed of a high-k material such as Al₂O₃, HfO₂, TiO₂, ZrO₂, Y₂O₃, Ta₂O₅, or La₂O₃, and electrical characteristics of the oxide layer are improved by incorporation using the neutral beams.

12. The apparatus of claim 6, wherein the substrate includes one of a silicon-oxide-nitride-oxide-silicon (SONOS) substrate, a tantalium-aluminium oxide-nitride-oxide-silicon (TANOS) substrate and a silicon-aluminium oxide-nitride-oxide-silicon (SANOS) substrate.
